(19) United States
(12) Patent Application Publication
(10) Pub. No.: US 2016/0218021 A1
(43) Pub. Date: Jul. 28, 2016

(54) SEMICONDUCTOR PACKAGE AND METHOD OF MANUFACTURING THE SAME

(71) Applicant: Advanced Semiconductor Engineering, Inc., Kaohsiung (TW)

(72) Inventors: Bernd Karl APPELT, Kaohsiung (TW); Kay Stefan ESSIG, Kaohsiung (TW); William T. CHEN, Kaohsiung (TW); Yuan-Chang SU, Kaohsiung (TW)

(73) Assignee: Advanced Semiconductor Engineering, Inc., Kaohsiung (TW)

(21) Appl. No.: 14/606,138

(22) Filed: Jan. 27, 2015

(51) Int. Cl. H01L 21/56; H01L 25/00; H01L 21/48; H01L 25/065; H01L 23/498; H01L 23/31

(52) U.S. Cl. CPC H01L 21/568; H01L 23/49816; H01L 23/49838; H01L 23/3157; H01L 21/4853; H01L 25/0657; H01L 25/0655; H01L 25/50; H01L 2225/06513

(57) ABSTRACT

The present disclosure relates to a semiconductor package and method of manufacturing the same. The semiconductor package includes a first die, a plurality of conductive pads, a package body and a plurality of first traces. The plurality of conductive pads electrically connect to the first die, and each of the plurality of conductive pads has a lower surface. The package body encapsulates the first die and the plurality of conductive pads and exposes the lower surface of each of the plurality of conductive pads from a lower surface of the package body. The plurality of first traces are disposed on the lower surface of the package body and are connected to the lower surface of each of the plurality of conductive pads. A thickness of each of the plurality of first traces is less than 100 μm.

### BACKGROUND

1. Technical Field

The present disclosure relates to a semiconductor package and method of manufacturing the same.

2. Description of the Related Art

Recent advances in semiconductor package technology have led to the development of packaging techniques which provide for the continuing miniaturization of the semiconductor package. These advancements have also led to the development of a wide variety of new and differing types of semiconductor packages.

Examples of semiconductor packages may include a flip-chip package, a leadframe package, etc. In the flip-chip package, a semiconductor chip is arranged to be opposite to an interconnect substrate so that first pads of the semiconductor chip are electrically connected to second pads of the interconnect substrate one-to-one through conductive bumps. In the leadframe package, a leadframe can be fabricated from a metal, for example, copper, and typically includes a paddle which is secured to the body of the leadframe and typically situated at the center of the leadframe. The leadframe also includes a number of leads which are secured to the frame.

A thickness of 100 micrometers (μm) or more is typically required for an interconnect substrate used in the flip-chip technology and a leadframe used in the leadframe package to provide sufficient stiffness for semiconductor processing, which may further limit size reduction of the semiconductor package. It would be desirable to have a thinner semiconductor package and method of manufacturing the same.

### SUMMARY

In accordance with an embodiment of the present disclosure, a semiconductor package includes a first die, a plurality of conductive pads, a package body and a plurality of first traces. The plurality of conductive pads electrically connect to the first die, and each of the plurality of conductive pads has a lower surface. The package body encapsulates the first die and the plurality of conductive pads and exposes the lower surface of each of the plurality of conductive pads from a lower surface of the package body. The plurality of first traces are disposed on the lower surface of the package body and connected to the lower surface of each of the plurality of conductive pads. A thickness of each of the plurality of first traces is less than 100 μm.

In accordance with an embodiment of the present disclosure, a semiconductor package includes a first die and a plurality of conductive pads electrically connected to the first die, and each of the plurality of conductive pads has a lower surface. A plurality of first traces is connected to the lower surface of each of the plurality of conductive pads. A package body encapsulates the first die, the plurality of conductive pads and the plurality of first traces, and exposes the lower surface of each of the plurality of conductive traces from a lower surface of the package body.

In accordance with an embodiment of the present disclosure, a method for manufacturing a semiconductor package includes: providing a carrier; disposing a metal foil on the carrier; forming a plurality of conductive structures on the metal foil; disposing a first die on the metal foil and electrically connecting the first die to the conductive structures; encapsulating the first die and the plurality of conductive structures; removing the carrier; and removing part of the metal foil to form a plurality of first traces, wherein the plurality of first traces are connected to the conductive structures.

### BRIEF DESCRIPTION OF THE DRAWINGS

FIG. 1 illustrates a semiconductor package in accordance with an embodiment of the present disclosure;

FIG. 2 illustrates a semiconductor package in accordance with another embodiment of the present disclosure;

FIG. 3 illustrates a semiconductor package in accordance with another embodiment of the present disclosure;

FIG. 4A, FIG. 4B, FIG. 4C, FIG. 4D, FIG. 4E, FIG. 4F, FIG. 4G and FIG. 4H illustrate a manufacturing method in accordance with an embodiment of the present disclosure;

FIG. 5 illustrates a semiconductor package in accordance with another embodiment of the present disclosure;

FIG. 6 illustrates a semiconductor package in accordance with another embodiment of the present disclosure;

FIG. 7 illustrates a semiconductor package in accordance with another embodiment of the present disclosure;

FIG. 8 illustrates a semiconductor package in accordance with another embodiment of the present disclosure;

FIG. 9A, FIG. 9B, FIG. 9C, FIG. 9D, FIG. 9E, FIG. 9F, FIG. 9G and FIG. 9H illustrate a manufacturing method in accordance with an embodiment of the present disclosure;

FIG. 10 illustrates a semiconductor package in accordance with another embodiment of the present disclosure;

FIG. 11A, FIG. 11B, FIG. 11C, FIG. 11D, FIG. 11E, FIG. 11F, FIG. 11G, and FIG. 11H illustrate a manufacturing method in accordance with another embodiment of the present disclosure;

FIG. 12 illustrates a semiconductor package in accordance with another embodiment of the present disclosure;

FIG. 13 illustrates a semiconductor package in accordance with another embodiment of the present disclosure;

FIG. 14 illustrates a semiconductor package in accordance with another embodiment of the present disclosure;

FIG. 15 illustrates a semiconductor package in accordance with another embodiment of the present disclosure;

FIG. 16 illustrates a semiconductor package in accordance with another embodiment of the present disclosure; and

FIG. 17 illustrates a semiconductor package in accordance with another embodiment of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

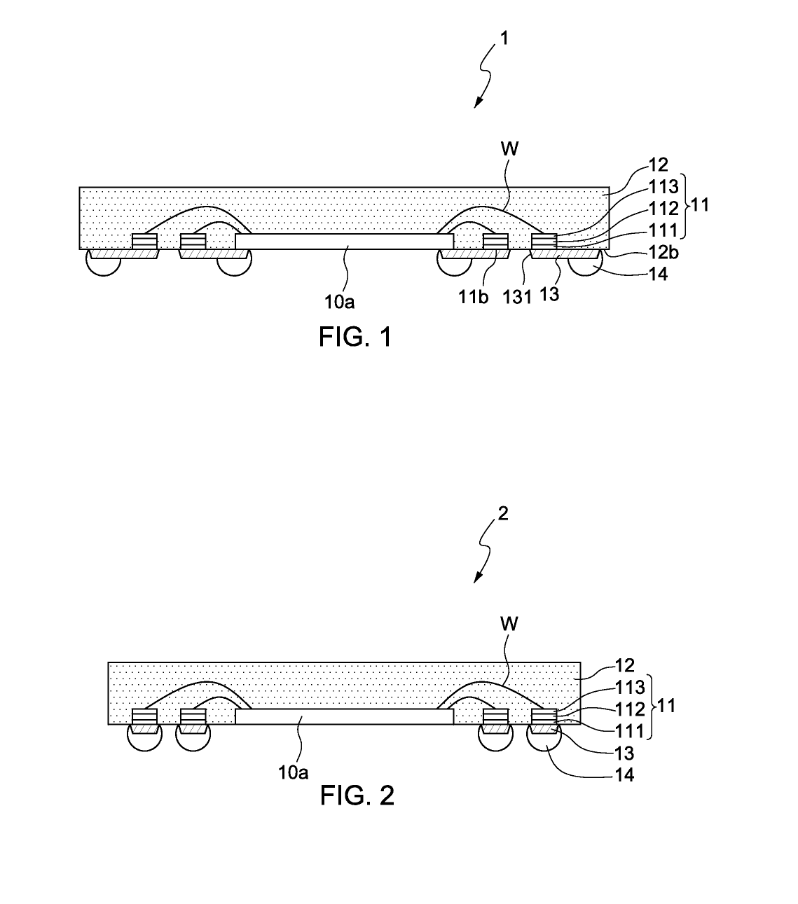

Referring to FIG. 1, illustrating a semiconductor package in accordance with an embodiment of the present disclosure, a semiconductor package 1 includes a die 10a, a plurality of conductive structures 11, a package body 12, a plurality of traces 13 and a plurality of electrical connection elements 14.

The die 10a may be, but is not limited to, an integrated circuit (IC) formed on or in a silicon substrate. The die 10a may be, but is not limited to, a wire-bond package type semiconductor chip.

Each of the plurality of conductive structures 11 has a multi-layer structure, which may include, for example, a first conductive metal layer 111, a second conductive metal layer 112 and a third conductive metal layer 113. The first conductive metal layer 111 may include, but is not limited to, gold (Au) or another suitable metal or alloy. The second conductive metal layer 112 may include, but is not limited to, Nickel (Ni) or another suitable metal or alloy. The third conductive metal layer 113 may include, but is not limited to, gold (Au) or another suitable metal or alloy. In accordance with another embodiment of the present disclosure, each of the plurality of conductive structures 11 has a single-layer structure. The plurality of conductive structures 11 are electrically connected to the die 10a by conductive metal wires “W”. Each of the plurality of conductive structures 11 has a lower surface 11b.

The package body 12 may include, but is not limited to, a molding compound or pre-impregnated composite fibers (e.g., pre-preg). Examples of a molding compound may include but are not limited to an epoxy resin having fillers dispersed therein. Examples of a pre-preg may include but are not limited to a multi-layer structure formed by stacking or laminating a number of pre-impregnated material/sheets. The package body 12 has a lower surface 12b. The package body 12 encapsulates the die 10a and the plurality of conductive structures 11 and exposes the lower surface 11b of each of the plurality of conductive structures 11 from the lower surface 12b of the package body 12.

The plurality of traces 13 are disposed on the lower surface 12b of the package body 12 and connected to the lower surface 11b of respective ones of the plurality of conductive structures 11. Each of the plurality of traces 13 has a thickness which is less than about 100 μm. For example, the thickness is less than about 100 μm, less than about 95 μm, less than about 90 μm, less than about 85 μm, less than about 80 μm, or less than about 75 μm. The term ‘thickness’ is used to describe a dimension in the vertical direction in the context of the individual figures unless otherwise noted. Some of the plurality of traces 13 are horizontally extended on the lower surface 12b of the package body 12 to form a redistribution arrangement (fan-out/in). Some of the plurality of traces 13 may have at least one inclined sidewall 131. Each of the plurality of traces 13 may have an upper surface against the lower surface 12b of the package body 12 and the lower surface 11b of each of the plurality of conductive structures 11, and a bottom surface opposite the upper surface, wherein the top surface area is greater than the bottom surface area. In some embodiments, traces 13 include connection pads (not shown in FIG. 1), such as for land grid array (LGA) devices.

The electrical connection elements 14 may include, but are not limited to, solder bumps or solder balls. The plurality of electrical connection elements 14 are electrically connected to the plurality of traces 13. The plurality of electrical connection elements 14 cover part of the at least one inclined sidewall 131 of the plurality of traces 13.

In accordance with another example of the present disclosure, a non-solder attach technique may be used to attach the semiconductor package 1 to a system substrate (not shown in FIG. 1), for example a printed circuit board, and the plurality of electrical connection elements 14 are eliminated. The non-solder attach technique may include, for example, silver or copper paste sintering, or a direct copper to copper (Cu—Cu) attach technique.

Referring to FIG. 2, illustrating a semiconductor package in accordance with another embodiment of the present disclosure, a semiconductor package 2 is similar to the semiconductor package 1 as illustrated and described with reference to FIG. 1, except that all of the at least one inclined sidewalls 131 of the plurality of traces 13 are covered by the electrical connection elements 14.

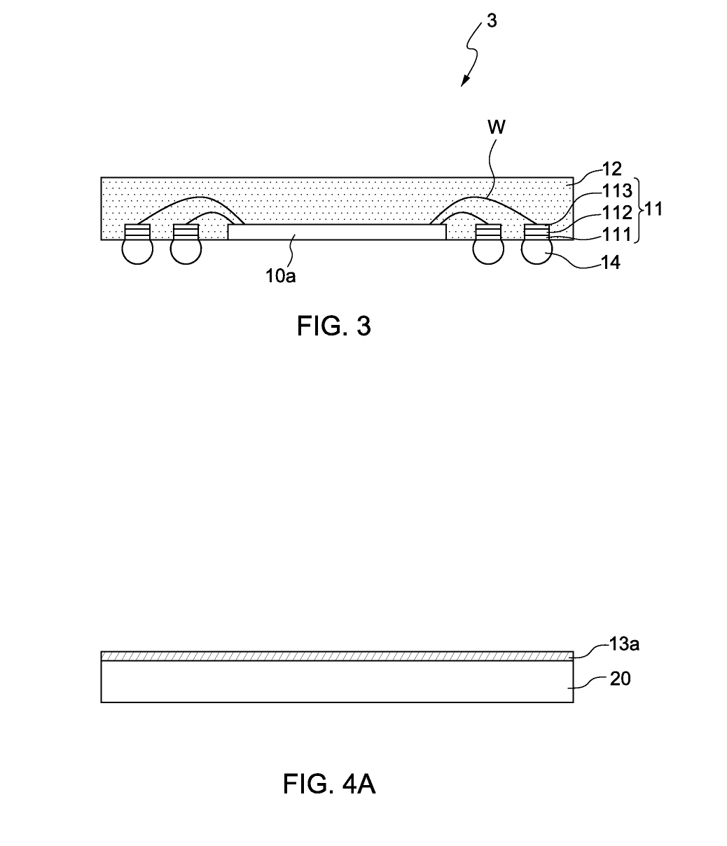

Referring to FIG. 3, illustrating a semiconductor package in accordance with another embodiment of the present disclosure, a semiconductor package 3 is similar to the semiconductor package 2 as illustrated and described with reference to FIG. 2, except that the plurality of traces 13 are eliminated and the plurality of electrical connection elements 14 are directly connected to respective ones of the plurality of conductive structures 11.

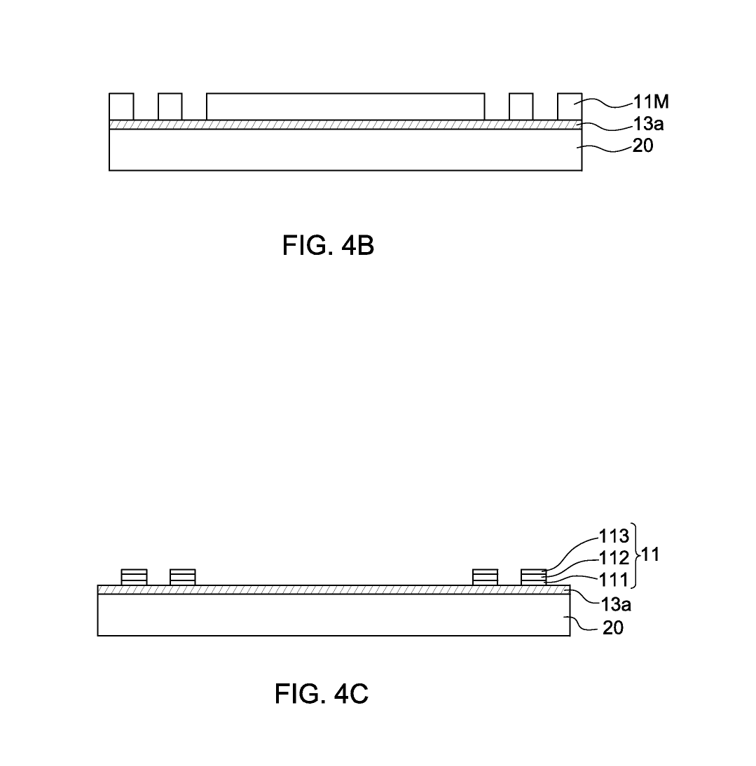

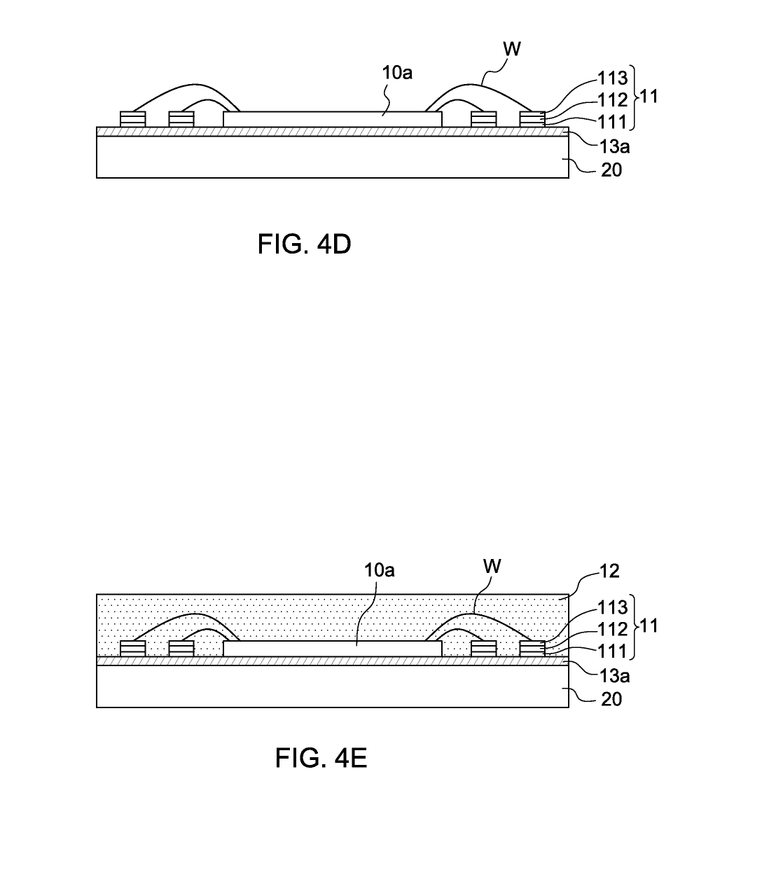

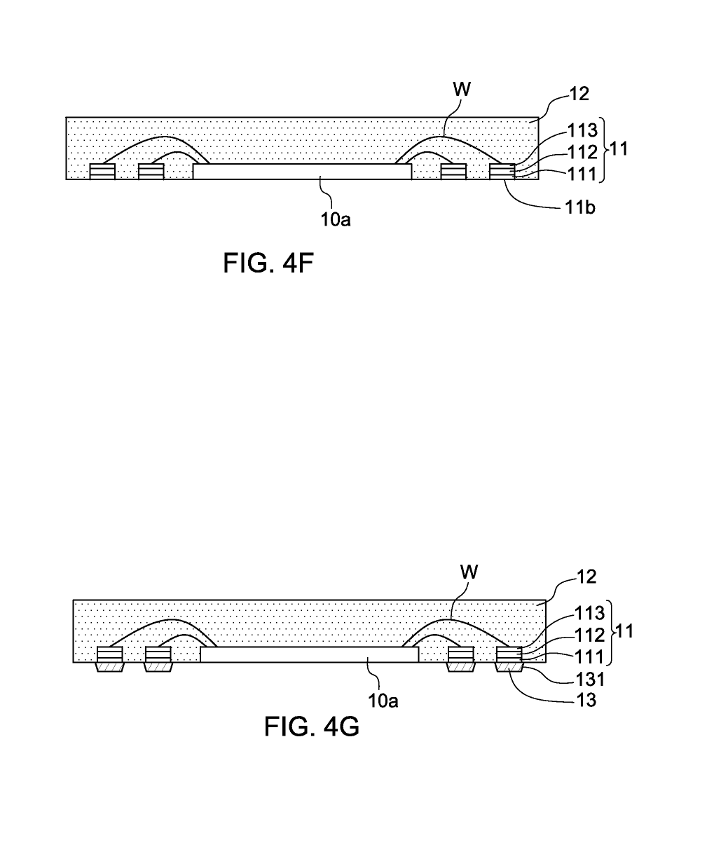

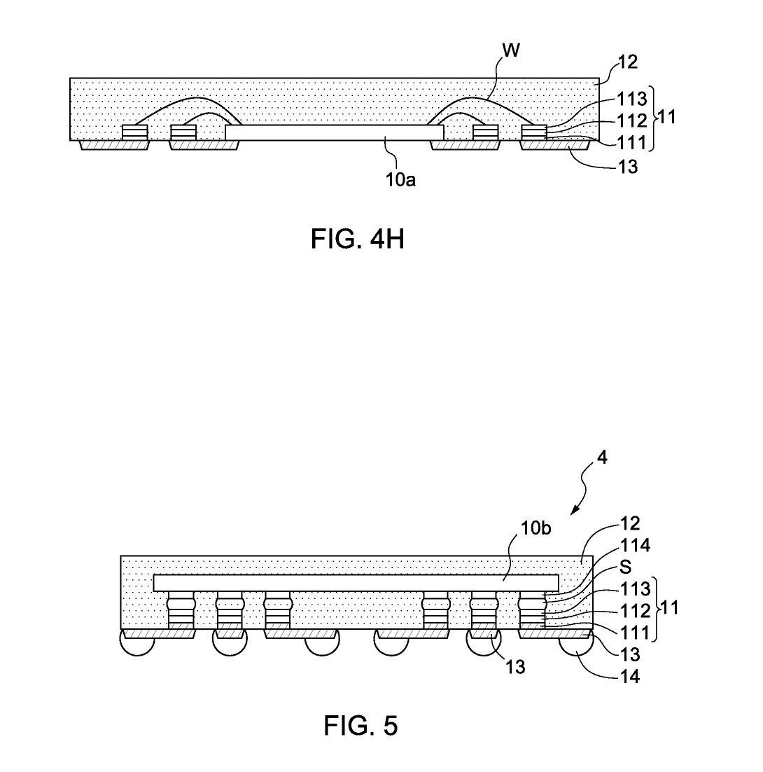

FIG. 4A, FIG. 4B, FIG. 4C, FIG. 4D, FIG. 4E, FIG. 4F, FIG. 4G and FIG. 4H illustrate a manufacturing method in accordance with an embodiment of the present disclosure.

Referring to FIG. 4A, a carrier 20 is provided. A metal foil 13a is formed on one side of the carrier 20 for a subsequent single-side process. The metal foil 13a has a thickness less than about 100 μm. For example, the thickness is less than about 100 μm, less than about 95 μm, less than about 90 μm, less than about 85 μm, less than about 80 μm, or less than about 75 μm. In accordance with another embodiment of the present disclosure, the metal foil 13a is formed on both sides of the carrier 20 for a subsequent double-side process. The metal foil 13a may be laminated, sputtered or plated onto the carrier 20. The carrier 20 may include, but is not limited to, stainless steel, nickel (Ni), nickel-iron alloy (e.g., INVAR), molybdenum alloy, or another suitable metal or alloy. The metal foil 13a may include, but is not limited to, copper or another suitable metal or alloy. A coefficient of thermal expansion (CTE) of the carrier 20 is substantially equal to that of the metal foil 13a, or alternatively selected to be closer to the CTE of the silicon die than to the CTE of the metal foil 13a.

Referring to FIG. 4B, a patterned mask 11M is formed on the metal foil 13a to expose part of the metal foil 13a. The patterned mask 11M may be formed, for example, by a photo-lithography technique.

Referring to FIG. 4C, a plurality of conductive structures 11 are formed on the exposed part of the metal foil 13a. Subsequently, the patterned mask 11M may be removed, such as by a stripping technique. The plurality of conductive structures 11 may be formed, for example, by photo-lithography and plating techniques.

Each of the plurality of conductive structures 11 may comprise a multi-layer structure, for example a three-layer structure which may include, but is not limited to, a first conductive metal layer 111, a second conductive metal layer 112 and a third conductive metal layer 113. The first conductive metal layer 111 may include, but is not limited to, gold (Au) or another suitable metal or alloy. The second conductive metal layer 112 may include, but is not limited to, Nickel (Ni) or another suitable metal or alloy. The third conductive metal layer 113 may include, but is not limited to, gold (Au) or another suitable metal or alloy.

In accordance with another embodiment of the present disclosure, each of the plurality of conductive structures 11 may have a four-layer structure which may include, but is not limited to, layers of copper (Cu), gold (Au), nickel (Ni), tin (SN) or silver (Ag), such as a Cu—Au—Ni—Au structure, a Cu—Ni—Sn—Ag structure, or other structure.

In accordance with another embodiment of the present disclosure, each of the plurality of conductive structures 11 may have a two-layer structure which may include, but is not limited to, a Ni—Au structure.

In accordance with another embodiment of the present disclosure, each of the plurality of conductive structures 11 has a single-layer structure which may include, but is not limited to, gold (Au) or another suitable metal or alloy.

Referring to FIG. 4D, a die 10a is attached to the metal foil 13a by adhesive (not shown in FIG. 4D), and is electrically connected to the plurality of conductive structures 11. A plurality of metal wires “W” may be used to connect a plurality of bonding pads (not shown) on the die 10a to the plurality of conductive structures 11 by wire-bond technology.

Referring to FIG. 4E, a package body 12 is formed on the metal foil 13a to encapsulate the die 10a, the plurality of conductive structures 11, the wires “W” and the metal foil 13a. A technique for forming the package body 12 may be, but is not limited to, a molding technology which uses a molding compound with the help of mold chase (not shown) to encapsulate the die 10a, the plurality of conductive structures 11, the wires “W” and the metal foil 13a. In another embodiment of the present disclosure, sheets made from pre-impregnated composite fibers (pre-preg) may be stacked or laminated to the metal foil 13a to form the package body 12.

Referring to FIG. 4F, the die 10a, the plurality of conductive structures 11, the package body 12, the wires “W” and the metal foil 13a as shown in FIG. 4E are separated from the carrier 20, and the metal foil 13a is subsequently removed. In other words, the carrier 20 is removed from the metal foil 13a and the structure formed thereon, such as by mechanically removing the carrier 20. Subsequent to the removal of the carrier 20, the metal foil 13a is removed, such as by the use of etching technology. Although carrier 20 is removed, the package body 12 can provide sufficient stiffness for handling in the subsequent process steps. A plurality of electrical connection elements 14 (not shown in FIG. 4F) may optionally be formed on a lower surface 11b of each of the plurality of conductive structures 11 to form the semiconductor package 3 as shown in FIG. 3. The electrical connection elements 14 may include, but are not limited to, solder bumps or solder balls. The electrical connection elements 14 may be formed by solder bump/ball implantation.

Referring to FIG. 4G, rather than proceeding from FIG. 4E to FIG. 4F, the carrier 20 as shown in FIG. 4E is removed from the metal foil 13a and the structure formed thereon, such as by mechanically removing the carrier 20. Subsequent to the removal of the carrier 20, portions of the metal foil 13a may be patterned, such as by a photo-lithography and etching technique, to form a plurality of traces 13 having a thickness less than about 100 μm. For example, the thickness is less than about 100 μm, less than about 95 μm, less than about 90 μm, less than about 85 μm, less than about 80 μm, or less than about 75 μm. Each of the plurality of traces 13 may have a tapered configuration with at least one inclined sidewall 131. A plurality of electrical connection elements 14 (not shown in FIG. 4G) may be formed by attaching solder balls or by plating solder bumps to electrically connect to the plurality of traces 13, and to cover the at least one inclined side wall 131 to form the semiconductor package 2 as shown in FIG. 2.

Referring to FIG. 4H, rather than proceeding from FIG. 4E to FIG. 4F, the carrier 20 as shown in FIG. 4E is removed from the metal foil 13a and the structure formed thereon, such as by mechanically removing the carrier 20. Subsequent to the removal of the carrier 20, portions of the metal foil 13a may be selectively removed, such as by etching, to form a plurality of traces 13. Each of the plurality of traces 13 may have a tapered configuration with at least one inclined sidewall 131. A plurality of electrical connection elements 14 (not shown in FIG. 4H) may be formed to electrically connect to the plurality of traces 13 and cover the at least one inclined side wall 131 to form the semiconductor package 1 as shown in FIG. 1. The electrical connection elements 14 may include, but are not limited to, solder bumps or solder balls. The electrical connection elements 14 may be formed by solder bump/ball implantation. It is contemplated that a dielectric layer (not shown in FIG. 4H) may be formed on the plurality of traces 13 and the package body 12 to expose part of the plurality of traces 13. The dielectric layer may be formed, for example, by coating or laminating photo-imageable dielectric material (e.g. solder mask) to the plurality of traces 13 and the package body 12, and then patterning by a photo-lithography technique to expose a portion of the plurality of traces 13.

Referring to FIG. 5, illustrating a semiconductor package in accordance with another embodiment of the present disclosure, a semiconductor package 4 is similar to the semiconductor package 1 as illustrated and described with reference to FIG. 1, except that instead of the wire-bond package type die 10a, a flip-chip type package die 10b is placed, and the wires “W” are eliminated. The die 10b has a plurality of bonding pads 114 which are bonded to the plurality of conductive structures 11, for example, to the third conductive metal layers 113 of conductive structures 11 through a solder layer “S” as shown in FIG. 5.

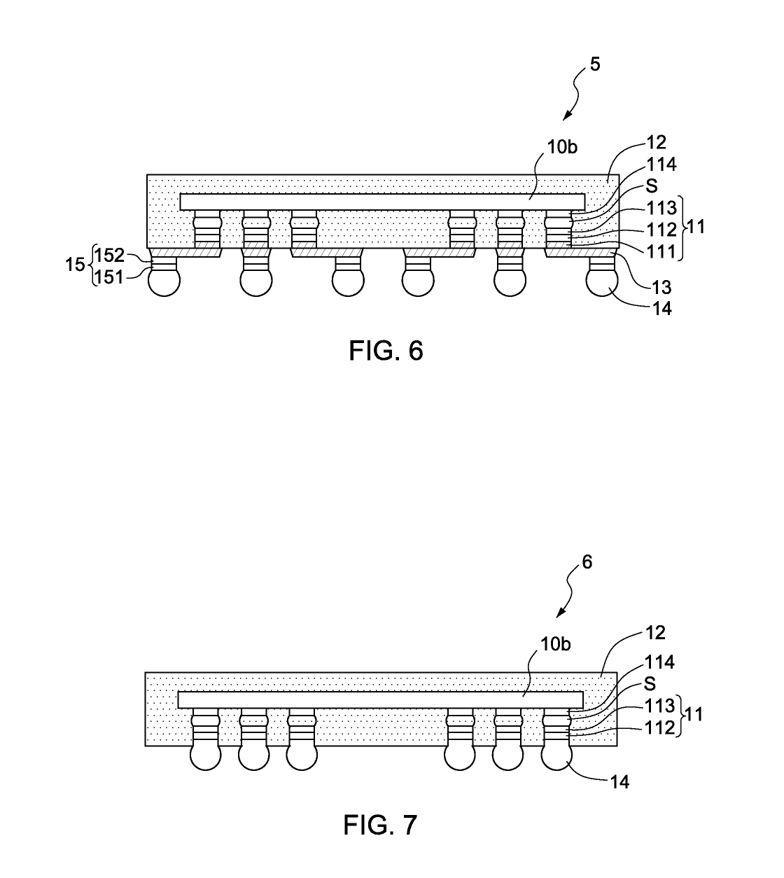

Referring to FIG. 6, illustrating a semiconductor package in accordance with another embodiment of the present disclosure, a semiconductor package 5 is similar to the semiconductor package 4 as illustrated and described with reference to FIG. 5, except that a plurality of conductive pads 15 are formed between each of the traces 13 and a respective electrical connection element 14. Each conductive pad 15 may include a first conductive metal layer 151 and a second conductive metal layer 152. The first conductive metal layer 151 may include, but is not limited to, gold (Au) or another suitable metal or alloy. The second conductive metal layer 152 may include, but is not limited to, Nickel (Ni) or another suitable metal or alloy.

Referring to FIG. 7, illustrating a semiconductor package in accordance with another embodiment of the present disclosure, a semiconductor package 6 is similar to the semiconductor package 3 as illustrated and described with reference to FIG. 3, except that, instead of the the wire-bond package type die 10a, a flip-chip type package die 10b is placed, the wires “W” and the first conductive metal layer 111 are eliminated, and the conductive structures 11 are recessed in the package body. The die 10b has a plurality of bonding pads 114 which are bonded to the plurality of conductive structures 11, for example, to the third conductive metal layers 113 of conductive structures 11 through a solder layer “S” as shown in FIG. 7.

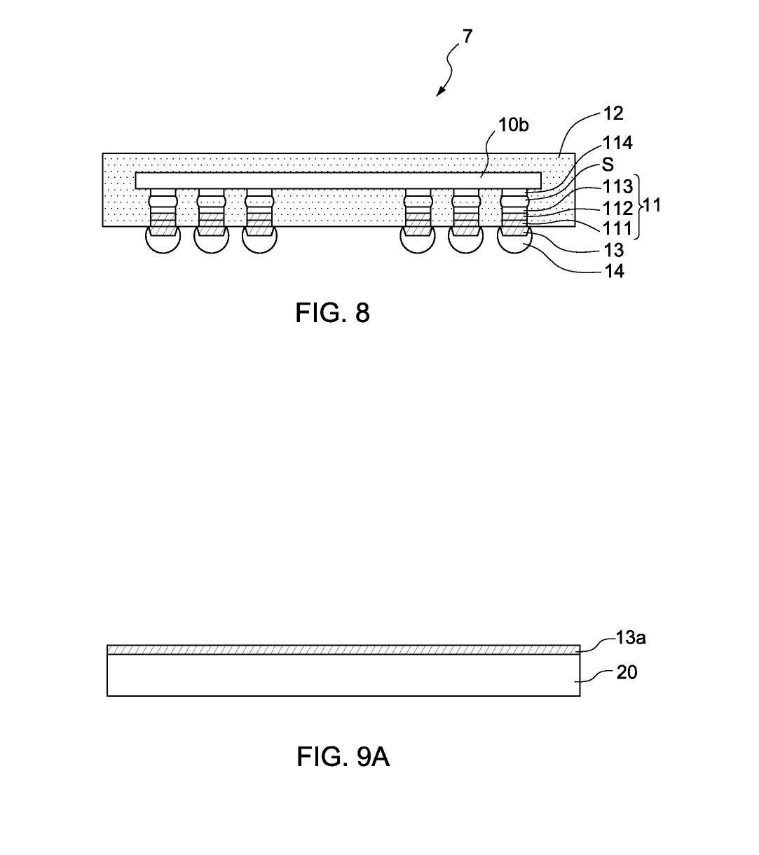

Referring to FIG. 8, illustrating a semiconductor package in accordance with another embodiment of the present disclosure, a semiconductor package 7 is similar to the semiconductor package 2 as illustrated and described with reference to FIG. 2, except that, instead of the wire-bond package type die 10a, a flip-chip type package die 10b is placed, and the wires “W” are eliminated. The die 10b has a plurality of bonding pads 114 which are bonded to the plurality of conductive structures 11, for example, to the third conductive metal layers 113 of conductive structures 11 through a solder layer “S” as shown in FIG. 8.

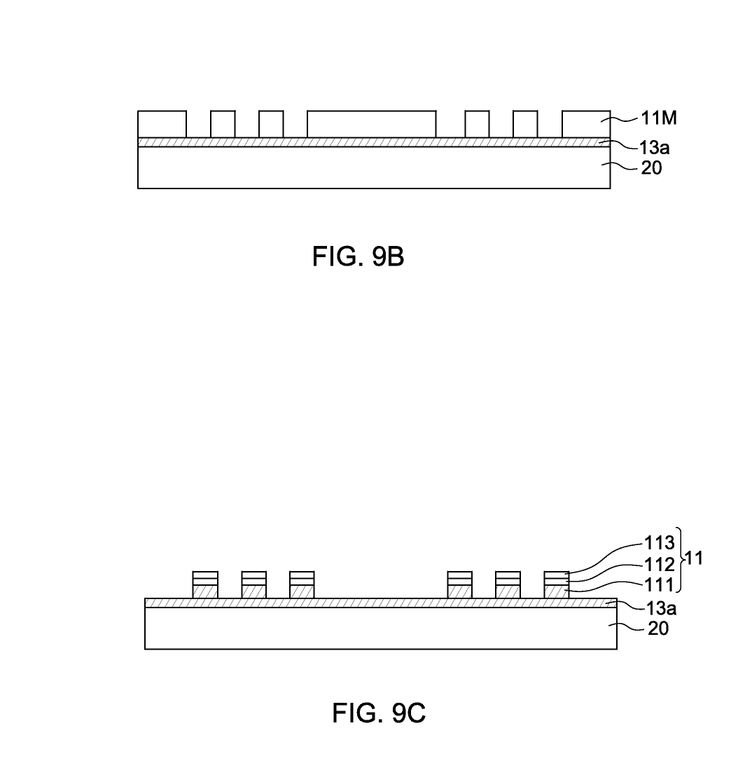

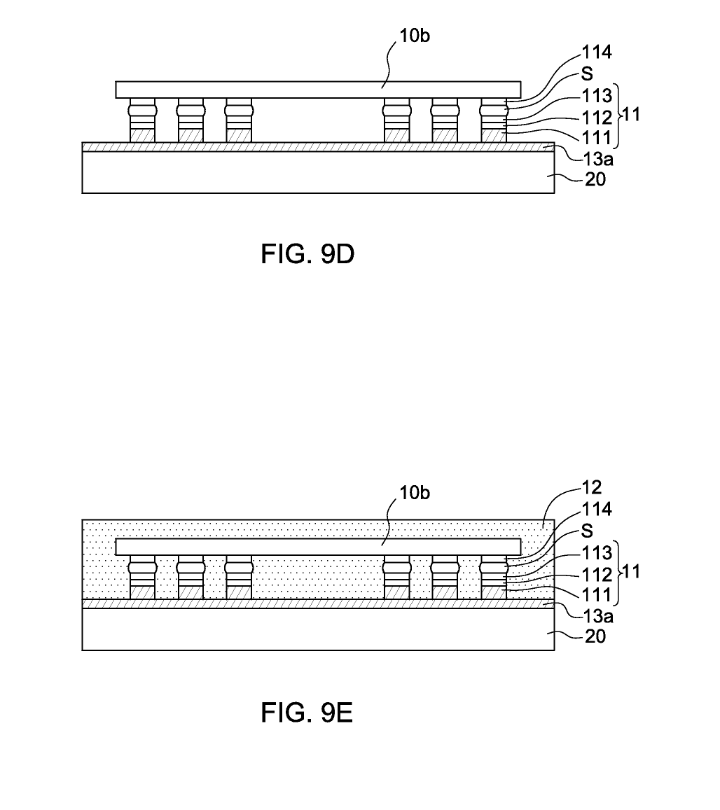

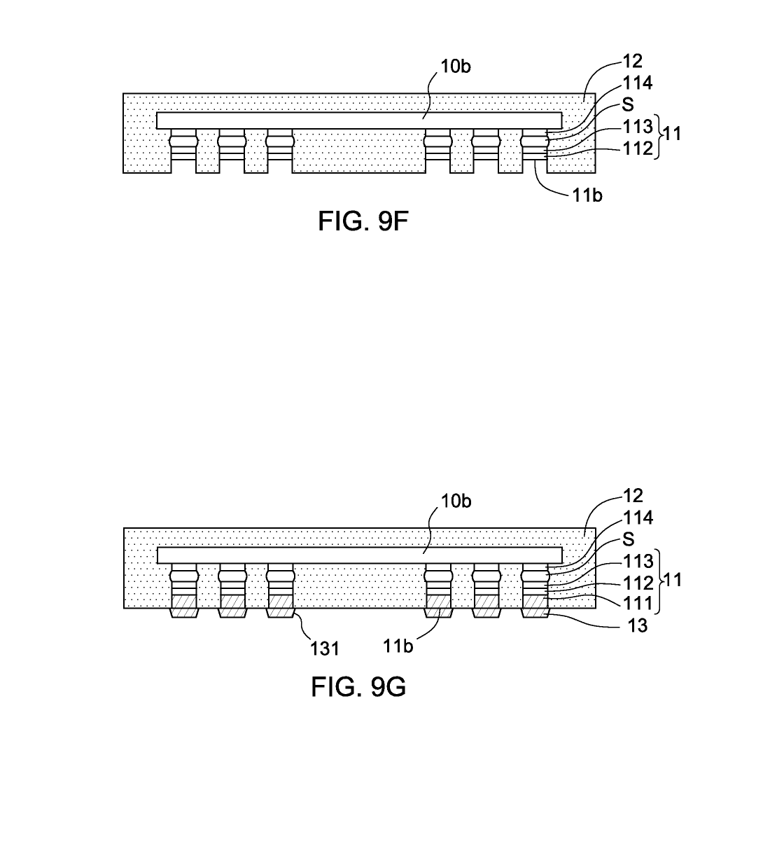

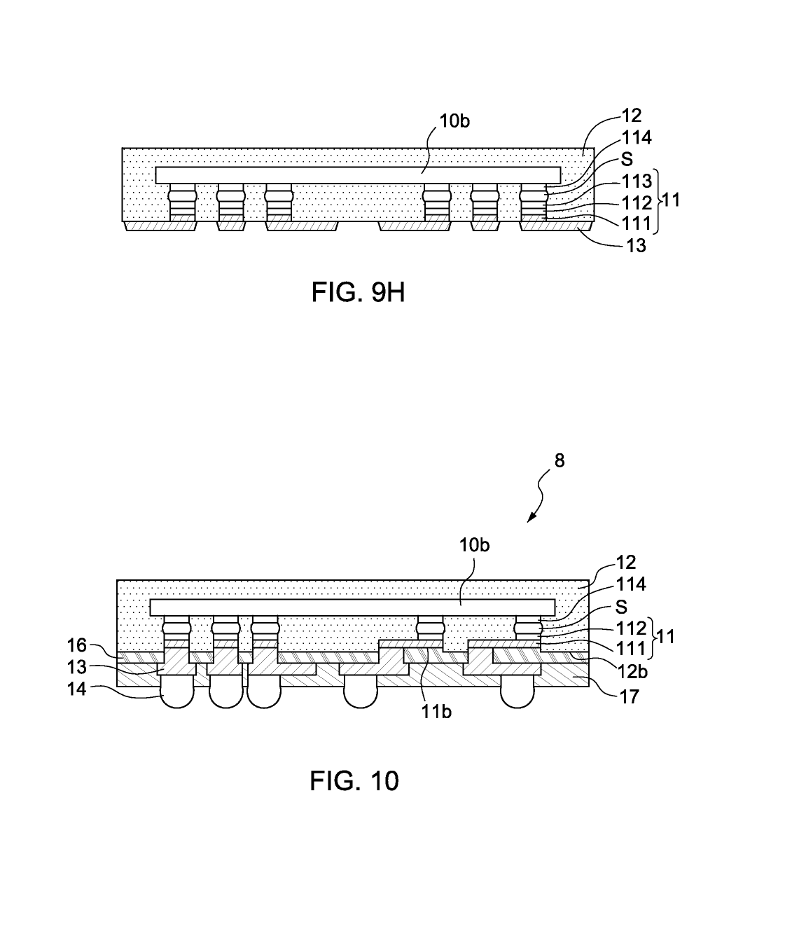

FIG. 9A, FIG. 9B, FIG. 9C, FIG. 9D, FIG. 9E, FIG. 9F, FIG. 9G and FIG. 9H illustrate a manufacturing method in accordance with an embodiment of the present disclosure.

Referring to FIG. 9A, a carrier 20 is provided. A metal foil 13a is formed on one side of the carrier 20 for a subsequent single-side process. The metal foil 13a has a thickness less than about 100 μm. For example, the thickness is less than about 100 μm, less than about 95 μm, less than about 90 μm, less than about 85 μm, less than about 80 μm, or less than about 75 μm. In accordance with another embodiment of the present disclosure, the metal foil 13a is formed on both sides of the carrier 20 for a subsequent double-side process. The metal foil 13a may be laminated, sputtered or plated onto the carrier 20. The carrier 20 may include, but is not limited to, stainless steel, INVAR, Ni, Mo-alloys, or another suitable metal or alloy. The metal foil 13a may include, but is not limited to, copper or another suitable metal or alloy. A coefficient of thermal expansion (CTE) of the carrier 20 is substantially equal to that of the metal foil 13a, or alternatively selected to be closer to the CTE of the silicon die than to the CTE of the metal foil 13a.

Referring to FIG. 9B, a patterned mask 11M is formed on the metal foil 13a to expose part of the metal foil 13a. The patterned masks 11M may be formed, for example, by a photo-lithography technique.

Referring to FIG. 9C, a plurality of conductive structures 11 are formed on the exposed part of the metal foil 13a. Subsequently, the patterned mask 11M may be removed, such as by a stripping technique. The plurality of conductive structures 11 may be formed, for example, by photo-lithography and plating techniques.

Each of the plurality of conductive structures 11 may comprise a multi-layer structure, for example a three-layer structure which may include, but is not limited to, a first conductive metal layer 111, a second conductive metal layer 112 and a third conductive metal layer 113. The first conductive metal layer 111 may include, but is not limited to, copper (Cu) or another suitable metal or alloy. The second conductive metal layer 112 may include, but is not limited to, Nickel (Ni) or another suitable metal or alloy. The third conductive metal layer 113 may include, but is not limited to, gold (Au) or another suitable metal or alloy.

In accordance with another embodiment of the present disclosure, each of the plurality of conductive structures 11 may have a single-layer structure.

In accordance with another embodiment of the present disclosure, an additional solder cap (not shown) may be disposed on each of the plurality of conductive structures 11.

Referring to FIG. 9D, a die 10b having a plurality of bonding pads 114 is bonded to the plurality of conductive structures 11 through a solder layer “S”.

Referring to FIG. 9E, a package body 12 is formed on the metal foil 13a to encapsulate the die 10b, the plurality of conductive structures 11 and the metal foil 13a. A technique for forming the package body 12 may be, but is not limited to, a molding technology which uses a molding compound with the help of mold chase (not shown) to encapsulate the die 10b, the plurality of conductive structures 11 and the metal foil 13a.

Referring to FIG. 9F, the die 10b, the plurality of conductive structures 11, the package body 12 and the metal foil 13a as shown in FIG. 9E are separated from the carrier 20, and the first conductive metal layers 111 of conductive structures 11 and the metal foil 13a are subsequently removed. In other words, the carrier 20 is removed from the metal foil 13a and the structure formed thereon, such as by mechanically removing the carrier 20. Subsequent to the removal of the carrier 20, the first conductive metal layers 111 of conductive structures 11 and the metal foil 13a are removed, such as by the use of etching technology. Although carrier 20 is removed, the package body 12 can provide sufficient stiffness for handling in the subsequent process steps. A plurality of electrical connection elements 14 (not shown in FIG. 9F) may be formed on a lower surface 11b of each of the plurality of conductive structures 11 to form the semiconductor package 6 as shown in FIG. 7. The electrical connection elements 14 may include, but are not limited to, solder bumps or solder balls. The electrical connection elements 14 may be formed by solder bump/ball implantation.

Referring to FIG. 9G, rather than proceeding from FIG. 9E to FIG. 9F, the carrier 20 as shown in FIG. 9E is removed from the metal foil 13a and the structure formed thereon, such as by mechanically removing the carrier 20. Subsequent to the removal of the carrier 20, portions of the metal foil 13a may be patterned, such as by a photo-lithography and etching technique, to form a plurality of traces 13 having a thickness less than about 100 μm. For example, the thickness is less than about 100 μm, less than about 95 μm, less than about 90 μm, less than about 85 μm, less than about 80 μm, or less than about 75 μm. Each of the plurality of traces 13 may have a tapered configuration with at least one inclined sidewall 131. A plurality of electrical connection elements 14 (not shown in FIG. 9G) may be formed by attaching solder balls or by plating solder bumps to electrically connect to the plurality of traces 13 and cover the at least one inclined side wall 131 to form the semiconductor package 7 as shown in FIG. 8.

Referring to FIG. 9H, rather than proceeding from FIG. 9E to FIG. 9F, the carrier 20 as shown in FIG. 9E is removed from the metal foil 13a and the structure formed thereon, such as by mechanically removing the carrier 20. Subsequent to the removal of the carrier 20, portions of the metal foil 13a may be selectively removed, such as by etching, to form a plurality of traces 13 electrically connected to the plurality of conductive structures 11. Each of the plurality of traces 13 may have a tapered configuration with at least one inclined sidewall 131. A plurality of electrical connection elements 14 (not shown in FIG. 9H) may be formed to electrically connect to the plurality of traces 13 and cover the at least one inclined side wall 131 to form the semiconductor package 4 as shown in FIG. 5. The electrical connection elements 14 may include, but are not limited to, solder bumps or solder balls. The electrical connection elements 14 may be formed by solder bump/ball implantation. A plurality of conductive pads (e.g., conductive pads 15 including layers 151 and 152) may be formed between the plurality of traces 13 and the electrical connection elements 14 to form the semiconductor package 5 as shown in FIG. 6.

Referring to FIG. 10, illustrating a semiconductor package in accordance with another embodiment of the present disclosure, a semiconductor package 8 includes a die 10b, a conductive structure 11, a package body 12, a plurality of traces 13, a plurality of electrical connection elements 14, a dielectric layer 16, an isolation layer 17 and a solder layer “S”. In FIG. 10, the first conductive metal layer 111 of conductive structure 11 is formed as a plurality of traces 111, and the second conductive metal layer 112 of conductive structure 11 is formed as a plurality of conductive pads 112.

The die 10b may be, but is not limited to, an integrated circuit (IC) formed on or in a silicon substrate. The die 10b may be, but is not limited to, a flip-chip package type semiconductor chip. The die 10b may have a plurality of bonding pads 114 on an active surface.

The traces 111 may include copper. The conductive pads 112 are positioned on the traces 111. Each conductive pad 112 may have a multi-layer structure, which may include, for example, a copper layer, a gold layer, a nickel layer, or another layer or layers of a suitable metal or alloy. The plurality of conductive pads 112 are bonded to the bonding pads 114 of die 10b through the solder layer “S”. Each of the plurality of conductive traces 111 has a lower 1 lb.

The package body 12 may include, but is not limited to, a molding compound or pre-impregnated composite fibers (e.g., pre-preg). Examples of a molding compound may include, but are not limited to, an epoxy resin having fillers dispersed therein. Examples of a pre-preg may include, but are not limited to, a multi-layer structure formed by stacking, or laminating a number of pre-impregnated material/sheets. The package body 12 has a lower surface 12b. The package body 12 encapsulates the die 10b, the plurality of conductive traces 111, and the conductive pads 112, and exposes the lower surface 11b of each of the plurality of conductive traces 111 from a lower surface 12b of the package body 12.

The dielectric layer 16 is disposed on the plurality of conductive traces 111 and the lower surface 12b of the package body 12. Part of the plurality of conductive traces 111 are exposed by the dielectric layer 16. The dielectric layer 16 may include, but is not limited to, a photo-imageable dielectric material, pre-impregnated composite fibers (e.g., pre-preg) or a material of solder mask. Examples of pre-preg may include, but are not limited to, a multi-layer structure formed by stacking or laminating a number of pre-impregnated materials/sheets.

The plurality of traces 13 are formed on the dielectric layer 16 and electrically connected to the exposed part of the plurality of traces 111. Each of the plurality of traces 13 has a thickness which is less or smaller than about 100 μm. For example, the thickness is less than about 100 μm, less than about 95 μm, less than about 90 μm, less than about 85 μm, less than about 80 μm, or less than about 75 μm. Some of the plurality of traces 13 are horizontally extended on the lower surface 12b of the package body 12 or the dielectric layer 16 to form a redistribution arrangement (fan-out/in). Some of the plurality of traces 13 may have a tapered configuration with at least one inclined sidewall (not shown in FIG. 10).

The isolation layer 17 is formed on the plurality of traces 13 and the dielectric layer 16. Part of the plurality of traces 13 are exposed by the isolation layer 17.

The electrical connection elements 14 are formed on the exposed part of the plurality of traces 13. The electrical connection elements 14 may include, but are not limited to, solder bumps or solder balls.

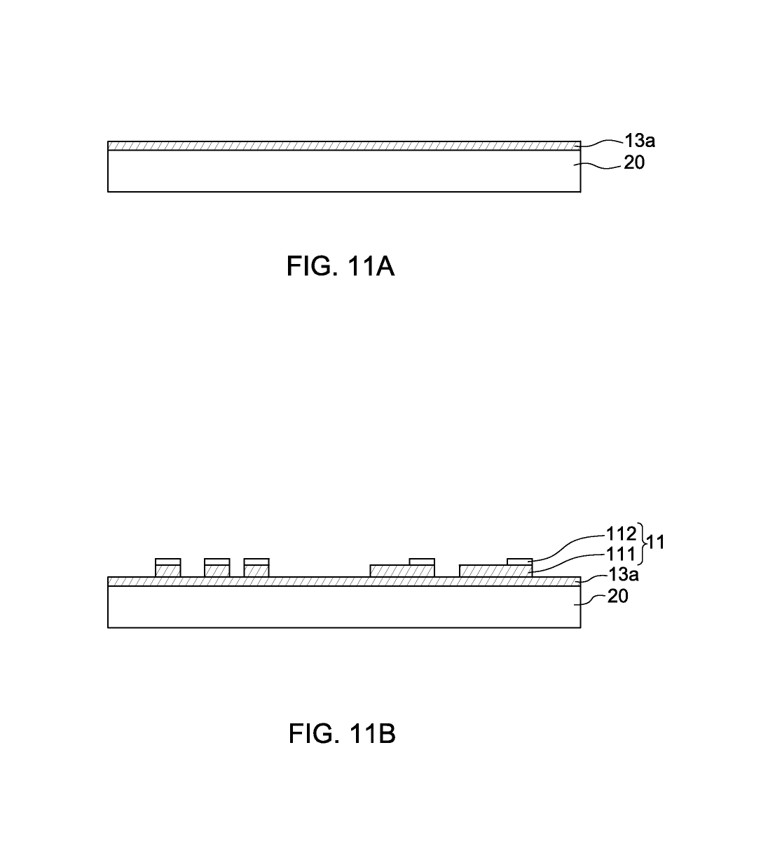

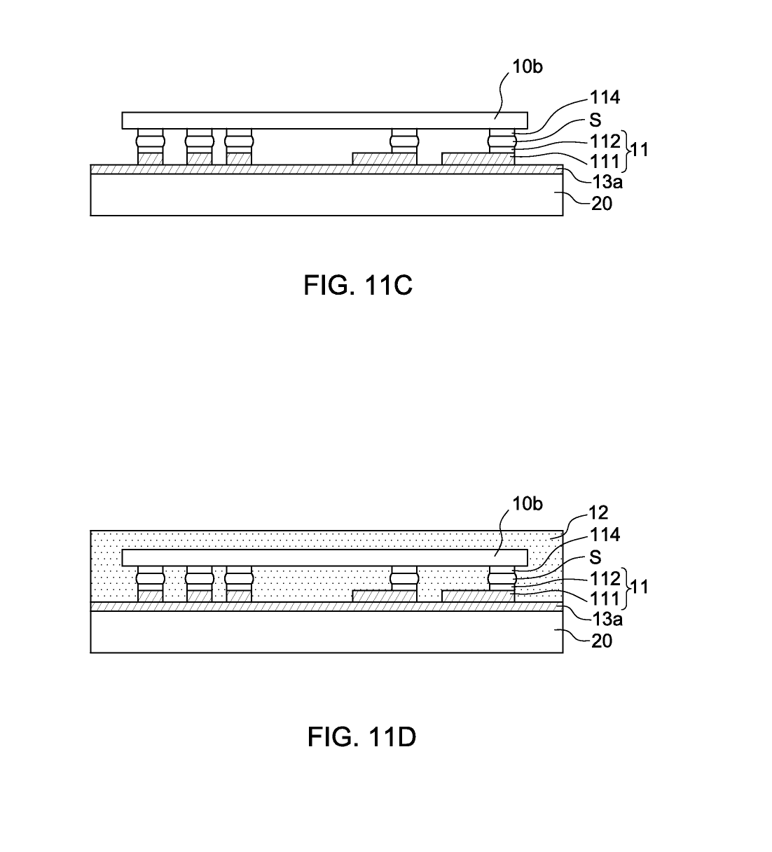

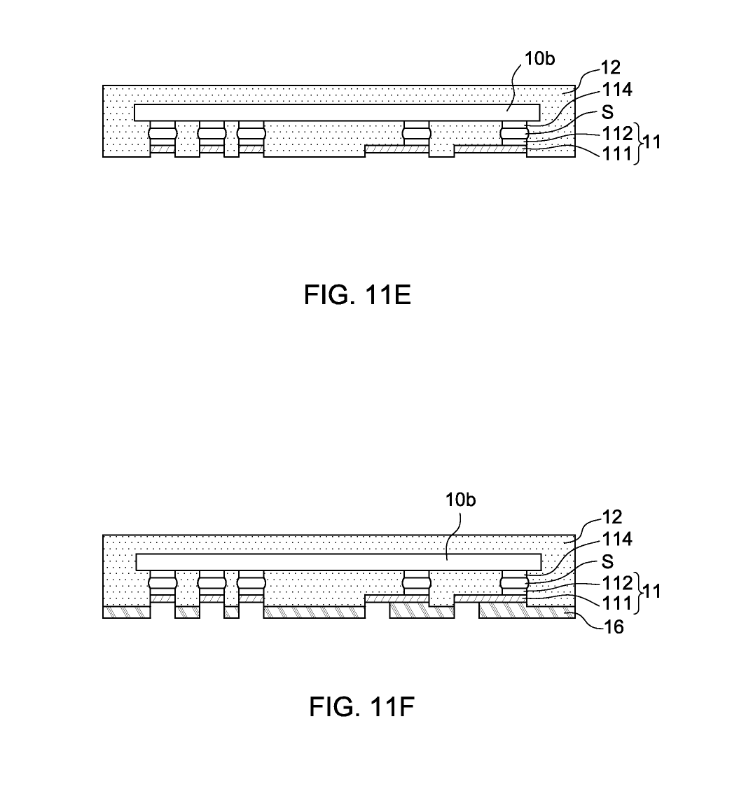

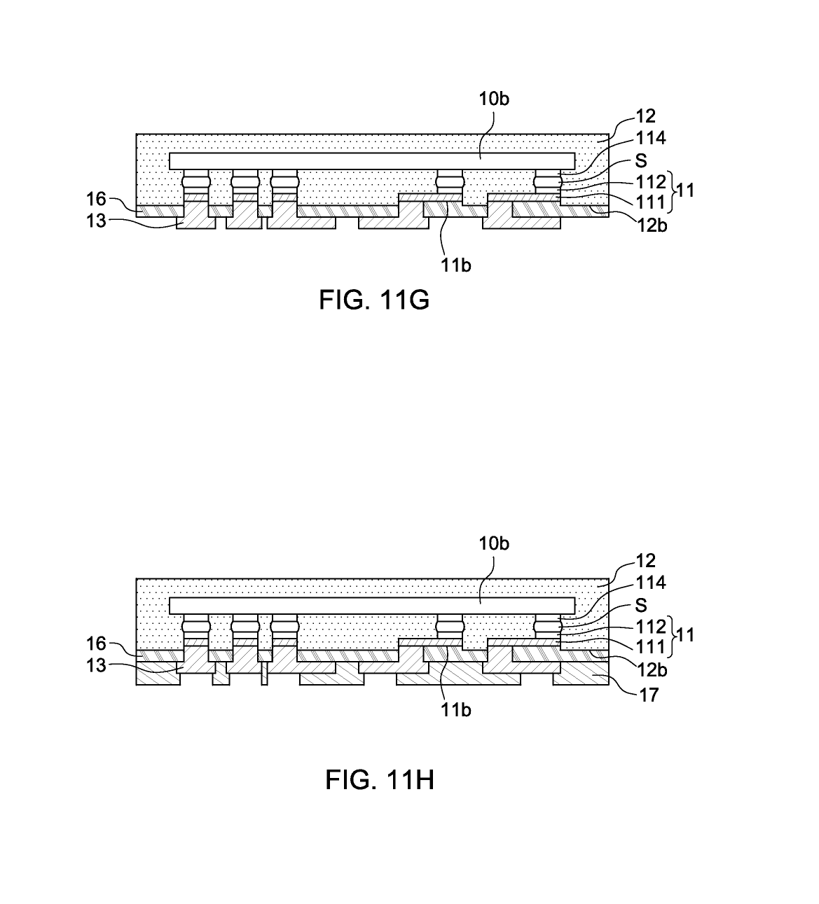

FIG. 11A, FIG. 11B, FIG. 11C, FIG. 11D, FIG. 11E, FIG. 11F, FIG. 11G, and FIG. 11H illustrate a manufacturing method in accordance with another embodiment of the present disclosure.

Referring to FIG. 11A, a carrier 20 is provided. A metal foil 13a is formed on one side of the carrier 20 for a subsequent single-side process. In accordance with another embodiment of the present disclosure, the metal foil 13a is formed on both sides of the carrier 20 for a subsequent double-side process. The metal foil 13a may be laminated, sputtered or plated onto the carrier 20. The carrier 20 may include, but is not limited to, stainless steel, INVAR, Ni, Mo-alloys, or another suitable metal or alloy. The metal foil 13a may include, but is not limited to, copper or another suitable metal or alloy. A coefficient of thermal expansion (CTE) of the carrier 20 is substantially equal to that of the metal foil 13a, or selected to be closer to the CTE of the silicon die than to the CTE of the metal foil 13a.

Referring to FIG. 11B, a first patterned conductive metal layer is formed on the metal foil 13a by photo-lithography and plating techniques to form a plurality of traces 111. A second patterned conductive metal is formed on the traces 111 by photo-lithography and plating techniques to form a plurality of conductive pads 112. A conductive pad 112 may have a smaller surface area than a corresponding trace 111.

Referring to FIG. 11C, a die 10b having a plurality of bonding pads 114 is bonded to the plurality of conductive pads 112 through a solder layer “S”.

Referring to FIG. 11D, a package body 12 is formed on the metal foil 13a to encapsulate the die 10b, the plurality of traces 111, the plurality of conductive pads 112 and the metal foil 13a. A technique for forming the package body 12 may be, but is not limited to, a molding technology which uses a molding compound with the help of mold chase (not shown) to encapsulate the die 10b, the plurality of traces 111, the plurality of conductive pads 112 and the metal foil 13a.

Referring to FIG. 11E, the die 10b, the plurality of traces 111, the plurality of conductive pads 112, the package body 12 and the metal foil 13a as shown in FIG. 11E are separated from the carrier 20, and the metal foil 13a is subsequently removed. In other words, the carrier 20 is removed from the metal foil 13a and the structure formed thereon, such as by mechanically removing the carrier 20. Subsequent to the removal of the carrier 20, the metal foil 13a is removed, such as by the use of etching technology. Although carrier 20 is removed, the package body 12 can provide sufficient stiffness for handling in the subsequent process steps.

Referring to FIG. 11F, a dielectric layer 16 is formed on the plurality of traces 111 and the package body 12 to expose part of the plurality of traces 111. The dielectric layer 16 may be formed, for example, by coating or laminating photo-imageable dielectric material to the plurality of traces 111 and the package body 12, and then patterning by a photo-lithography technique to exposed part of the plurality of traces 111. A seed layer (not shown in FIG. 11F) may be sputtered on the exposed part of the plurality of traces 111.

Referring to FIG. 11G, a plurality of traces 13 are formed on the dielectric layer 16 and on the exposed part of the plurality of traces 111. The plurality of traces 13 have a thickness less than about 100 μm. For example, the thickness is less than about 100 μm, less than about 95 μm, less than about 90 μm, less than about 85 μm, less than about 80 μm, or less than about 75 μm. The plurality of traces 13 are formed on the seed layer (not shown in FIG. 11G) on the exposed part of the plurality of traces 111 and are electrically connected to the plurality of traces 111. The plurality of traces 13 may be formed, for example, by sputtering, plating and etching techniques.

Referring to FIG. 11H, an isolation layer 17 is formed on the plurality of traces 13 and the dielectric layer 16 to expose part of the plurality of traces 13. Subsequently, a plurality of electrical connection elements 14 (not shown in FIG. 11H) are formed on the exposed part of the plurality of traces 13 to form the semiconductor package 8 as shown in FIG. 10.

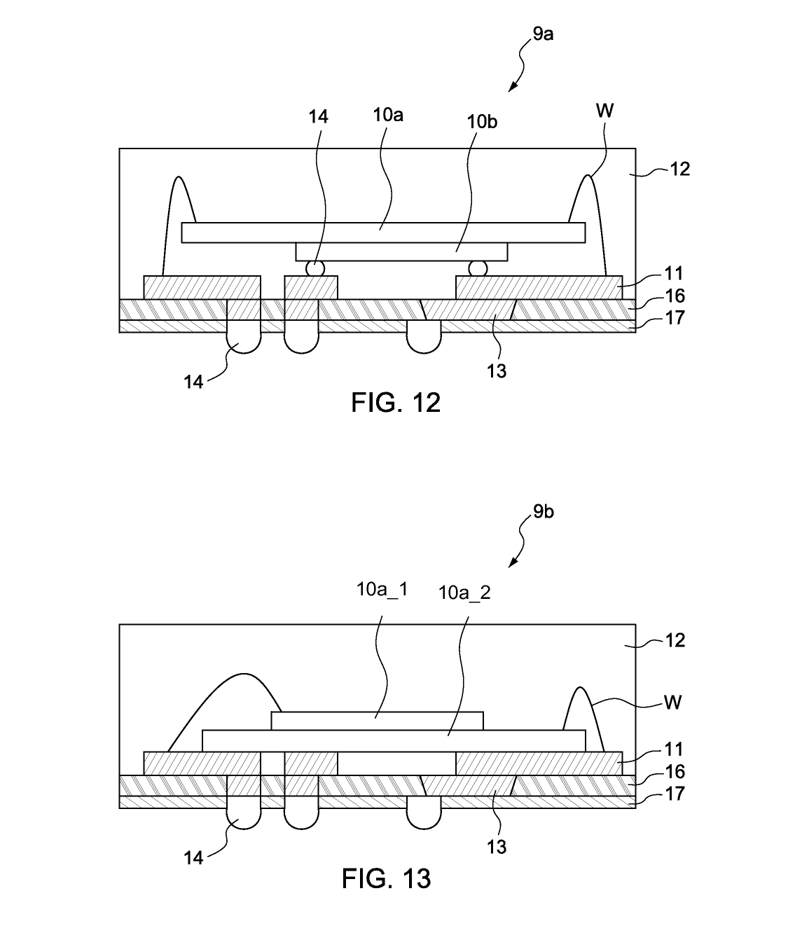

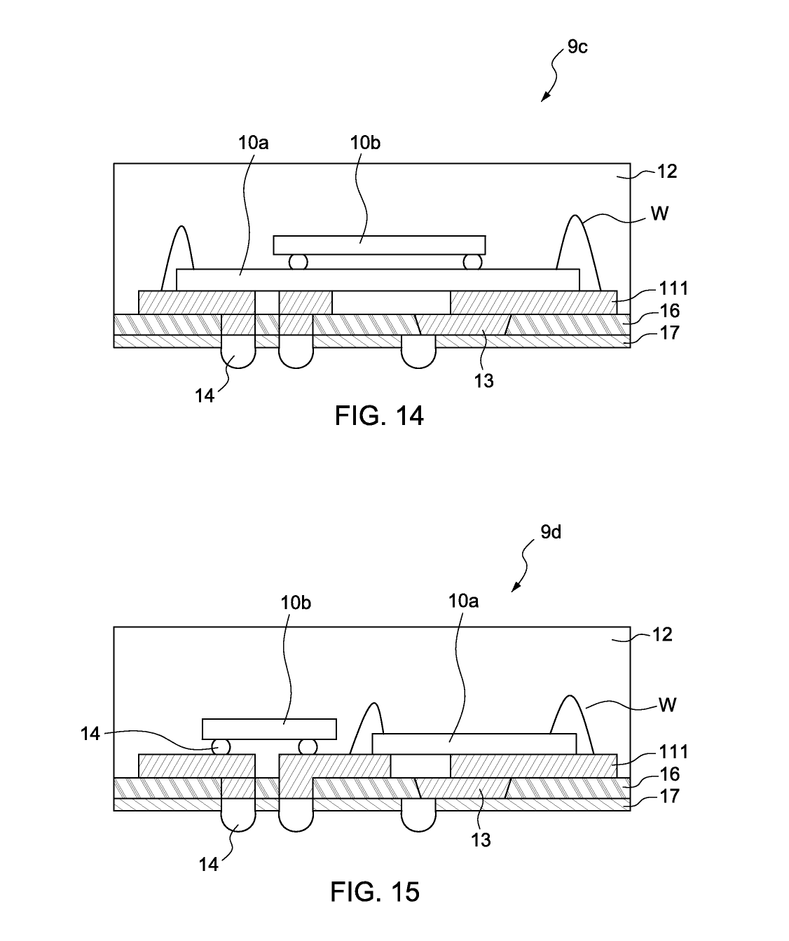

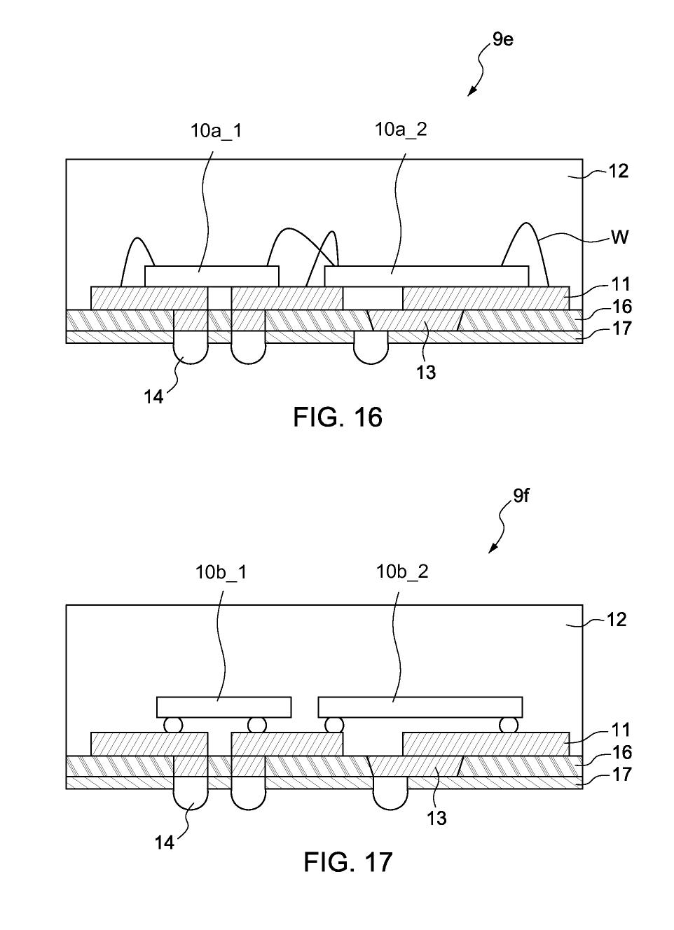

In each of the embodiments illustrated in FIGS. 1-11H, one die 10a or 10b is illustrated. Alternatively, a semiconductor package in accordance with this disclosure may include two or more dies. Examples are provided in FIGS. 12-17. In FIG. 12, a wire-bond die 10a is positioned on top of a flip-chip die 10b. In FIG. 13, a wire-bond die 10a_1 is positioned on top of a wire-bond die 10a_2. In FIG. 14, a flip-chip die 10b is positioned on top of a wire-bond die 10b. In FIG. 15, a wire-bond die 10a is positioned next to a flip-chip die 10b. In FIG. 16, a wire-bond die 10a_1 is positioned next to a wire-bond die 10a_2. In FIG. 17, a flip-chip die 10b_1 is positioned next to a flip-chip die 10b_2. Other configurations are also possible, such as a combination of relative horizontal and vertical positioning of three or more dies. In each of FIGS. 12-17, electrical connection is made by bumps, balls, or wires as applicable, as described above. Electrical connections may be made directly between two or more dies, such as shown in FIGS. 14 and 16, and/or indirectly between two or more dies, such as shown in FIGS. 12, 15 and 17. Electrical connections may otherwise also be made between a die and ones of the plurality of conductive structures 11, as shown in FIGS. 12-17.

As used herein, the terms “substantially,” “substantial,” “approximately,” and “about” are used to describe and account for small variations. When used in conjunction with an event or circumstance, the terms can refer to instances in which the event or circumstance occurs precisely as well as instances in which the event or circumstance occurs to a close approximation. For example, the terms can refer to less than or equal to ±10%, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

In some embodiments, two surfaces can be deemed to be coplanar or substantially coplanar if a displacement between the two surfaces is small, such as no greater than 1 μm, no greater than 5 μm, or no greater than 10 μm.

While the present disclosure has been described and illustrated with reference to specific embodiments thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily be drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

1. A semiconductor package, comprising:
a first die;
a plurality of conductive pads electrically connected to the first die, and each of the plurality of conductive pads having a lower surface;
a package body encapsulating the first die and the plurality of conductive pads and exposing the lower surface of each of the plurality of conductive pads from a lower surface of the package body; and
a plurality of first traces disposed on the lower surface of the package body and connected to the lower surface of each of the plurality of conductive pads, wherein a thickness of each of the plurality of first traces is less than 100 micrometers.

2. The semiconductor package of claim 1, further comprising a plurality of solder balls electrically connected to respective ones of the plurality of first traces.

3. The semiconductor package of claim 1, wherein the plurality of first traces comprise at least one inclined side wall.

4. The semiconductor package of claim 3, further comprising a plurality of solder balls electrically connected to the plurality of first traces, and the solder balls cover the at least one inclined side wall of the plurality of first traces.

5. A semiconductor package, comprising:
a first die;
a plurality of conductive pads electrically connected to the first die, and each of the plurality of conductive pads having a lower surface;
a plurality of first traces connected to the lower surface of each of the plurality of conductive pads; and
a package body encapsulating the first die, the plurality of conductive pads and the plurality of first traces, and exposing the lower surface of each of the plurality of conductive traces from a lower surface of the package body.

6. The semiconductor package of claim 5, further comprising a dielectric layer formed on the plurality of first traces and the package body, and part of the plurality of first traces is exposed by the dielectric layer.

7. The semiconductor package of claim 6, further comprising a plurality of second traces formed on the dielectric layer and electrically connected to the exposed part of the plurality of first traces.

8. The semiconductor package of claim 7, further comprising an isolation layer formed on the plurality of second traces and the dielectric layer, and part of the plurality of second traces is exposed by the isolation layer.

9. The semiconductor package of claim 5, further comprising a second die stacked on the first die, and electrically connected to the first die.

10. The semiconductor package of claim 5, further comprising a second die disposed aside the first die, and electrically connected to the plurality of first traces, wherein the second die is electrically connected to the first die.

11-20. (canceled)

21. A semiconductor package, comprising:
a package body;
a conductive structure embedded in the package body, a lower surface of the conductive structure exposed from a surface of the package body;
a trace disposed on and in contact with the conductive structure, the trace comprising inclined sides; and
an electrical connection element disposed on the trace and covering at least one inclined side of the trace.

22. The semiconductor package of claim 21, the electrical connection element covering at least two inclined sides of the trace.

23. The semiconductor package of claim 21, further comprising a die encapsulated by the package body and a conductive pad on a lower surface of the die, the conductive pad exposed from the surface of the package body, wherein the trace is further disposed on the conductive pad.

24. The semiconductor package of claim 23, wherein the electrical connection element is further disposed on the conductive pad.

25. The semiconductor package of claim 21, wherein a thickness of the trace is less than 100 micrometers.

26. The semiconductor package of claim 21, wherein the conductive structure comprises a three-layer structure.

27. The semiconductor package of claim 26, the three-layer structure comprising a first gold layer, a second gold layer, and a nickel layer disposed between the first gold layer and the second gold layer.

28. The semiconductor package of claim 21, further comprising a first die and a second die disposed over the first die, the first die and the second die being encapsulated by the package body.

29. The semiconductor package of claim 21, further comprising a first die and a second die disposed adjacent to the first die, the first die and the second die being encapsulated by the package body.

30. The semiconductor package of claim 21, wherein the lower surface of the conductive structure is recessed from the surface of the package body.
